(19) United States
(12) Patent Application Publication
(10) Pub. No.: US 2025/0255056 A1
(43) Pub. Date: Aug. 7, 2025

(54) DISPLAY DEVICE AND MANUFACTURING METHOD THEREOF

(71) Applicant: AUO Corporation, Hsinchu City (TW)

(72) Inventor: Yi-Sheng Jhao, Hsinchu City (TW)

(73) Assignee: AUO Corporation, Hsinchu City (TW)

(21) Appl. No.: 18/826,202

(22) Filed: Sep. 6, 2024

(30) Foreign Application Priority Data
Feb. 1, 2024 (TW) 113103881

(51) Int. Cl. H01L 33/58; H01L 25/16

(52) U.S. Cl. CPC H10H 20/855; H01L 25/167; H10H 20/0363

(57) ABSTRACT

A display device includes a driving substrate, a plurality of light-emitting elements, a light-shielding layer and a sensor. The plurality of light-emitting elements and the sensor are disposed on the drive substrate. The light-shielding layer is disposed between the plurality of light-emitting and further covers part of an upper surface of the sensor, where satisfies the conditions of: H1>H2>H3; H1 is a height from a light-emitting surface of the light-emitting element to the driving substrate, H2 is a height of the light-shielding layer on the driving substrate, and H3 is the height from an upper surface of the light-shielding layer to the driving substrate. A method of manufacturing a display device is also proposed.

### CROSS-REFERENCE TO RELATED APPLICATION

This application claims the priority benefit of Taiwan application serial no. 113103881, filed on Feb. 1, 2024. The entirety of the above-mentioned patent application is hereby incorporated by reference herein and made a part of this specification.

### BACKGROUND

### Technical Field

The disclosure relates to an electronic device, and in particular relates to a display device and a manufacturing method thereof.

### Description of Related Art

In display devices, various types of sensors are commonly incorporated into the screen. For example, optical sensors are used for fingerprint recognition and ambient light sensors are used to sense ambient light intensity to adjust display brightness accordingly. Therefore, a display device possesses multiple sensing functions.

However, when a sensor is installed between the pixels of the display device, how to prevent other panel elements (e.g., the black matrix) from affecting the sensing signal so that the sensor maintains sensitivity is still a problem that relevant manufacturers intend to solve.

### SUMMARY

A display device with good display quality, high sensitivity sensor, and good capability to sense ambient light or receive external light signals, is provided in the disclosure.

A manufacturing method of a display device, which may reduce the thickness of the optical layer on the sensor, reduce the damage that the sensor may suffer during the manufacturing process, maintain the sensitivity of the sensor and the contrast of the display device, and improve the sensing performance of the display device, is provided in the disclosure.

An embodiment of the disclosure provides a display device, including a driving substrate, multiple light-emitting elements, a light-shielding layer and a sensor. The light-emitting elements and the sensor are disposed on the driving substrate. The light-shielding layer is disposed between the light-emitting elements and further covers part of an upper surface of the sensor, in which the following conditional expression is satisfied: H1>H2>H3. H1 is a height from a light-emitting surface of the light-emitting elements to the driving substrate. H2 is a height of the light-shielding layer on the driving substrate. H3 is a height from an upper surface of the light-shielding layer to the driving substrate.

An embodiment of the disclosure provides a manufacturing method of a display device, including the following operation. A driving substrate is disposed. Multiple light-emitting elements and a sensor are disposed on the driving substrate. A light-shielding layer is disposed on the light-emitting elements, on the sensor, and between the light-emitting elements. Part of the light-shielding layer on the sensor is first removed through a laser, and then another part of the light-shielding layer on the light-emitting elements and the sensor is removed.

Based on the above, for the display device, a portion of the light-shielding layer above the sensor may first be removed through a laser process, and then other processes (e.g., an etching process) may be used for a large-area removal of the rest of the light-shielding layer to avoid affecting the light output of the display beam. The laser process may accurately control the depth of the light-shielding layer, so even if the height of the sensor is less than the height of the light-emitting element, the display device and the manufacturing method thereof of the disclosure may still ensure that the thickness of the light-shielding layer on the sensor is low enough so as not to affect the ability of the sensor to receive external information while taking into account the light-shielding capability of the light-shielding layer at other locations, so that the sensor has good sensitivity. Therefore, the sensing capability of the display device is improved and high contrast is maintained.

In order to make the above-mentioned features and advantages of the disclosure comprehensible, embodiments accompanied with drawings are described in detail below.

### BRIEF DESCRIPTION OF THE DRAWINGS

FIG. 1 is a cross-sectional schematic diagram of a display device of an embodiment of the disclosure.

FIG. 2A to FIG. 2D are schematic diagrams of the manufacturing process of the display device of an embodiment of the disclosure.

FIG. 3A to FIG. 3B are respectively a top view schematic diagram and a cross-sectional schematic diagram of a laser process.

### DETAILED DESCRIPTION OF DISCLOSED EMBODIMENTS

The usages of “approximately”, “similar to”, “essentially” or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may indicate to be within one or more standard deviations of the indicated value, such as being within +30%, +20%, +15%, +10%, or +5%. Furthermore, the usages of “approximately”, “similar to”, “essentially” or “substantially” indicated throughout the specification may refer to a more acceptable deviation scope or standard deviation depending on measurement properties, cutting properties, or other properties, and all properties may not be applied with one standard deviation.

In the drawings, for clarity, the thickness of layers, films, plates, areas, and the like are magnified. It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect.

References of the exemplary embodiments of the disclosure are to be made in detail. Examples of the exemplary embodiments are illustrated in the drawings. If applicable, the same reference numerals in the drawings and the descriptions indicate the same or similar parts.

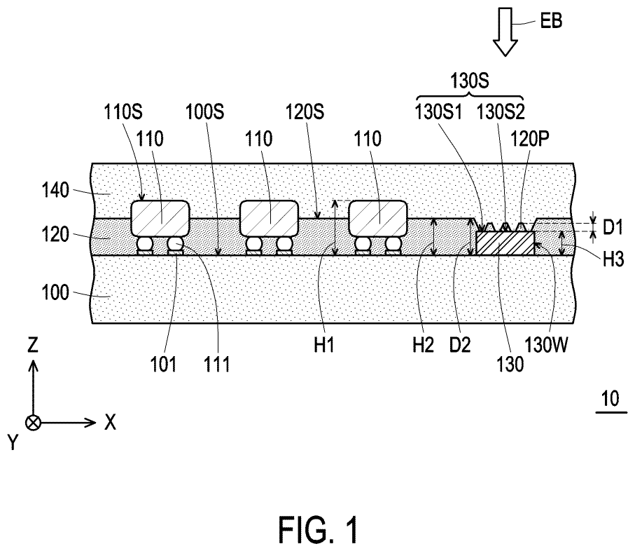

FIG. 1 is a cross-sectional schematic diagram of a display device of an embodiment of the disclosure. Referring to FIG. 1, the display device 10 may be used in a display with a sensing function, such as a smart phone, a smart home appliance, or an interactive screen, and the disclosure is not limited thereto. The display device 10 may include a driving substrate 100, multiple light-emitting elements 110, a light-shielding layer 120, and a sensor 130. The light-emitting elements 110 and the sensor 130 are disposed on the driving substrate 100 and are further electrically connected to the driving substrate 100.

In this embodiment, the driving substrate 100 includes a variety of signal lines (e.g., data lines, scan lines or power lines, not shown) and at least one drive circuit chip (not shown). The drive circuit chip, for example, has transistors or integrated circuits (ICs) that may be electrically connected to multiple light-emitting elements 110, and controls the display signals of the light-emitting elements 110 to provide a display screen, which is not limited thereto. For example, the driving substrate 100 adopts silicon wafer material and includes complementary metal oxide semiconductor (CMOS), thereby improving the response speed of each switching element in the driving substrate 100 and reducing power consumption to meet the requirements of fast response and high resolution of the display device 10. However, the disclosure is not limited thereto. In other embodiments, the driving substrate 100 may also be a printed circuit board (PCB). In other embodiments, the driving substrate 100 may also be a combination of a glass substrate and a pixel circuit layer. The pixel circuit layer is formed on a glass substrate by adopting a semiconductor process, and the pixel circuit layer may include active elements (e.g., thin film transistors) and various signal lines (e.g., data lines, scan lines, or power lines), but not limited thereto.

The light-emitting element 110 has a light-emitting surface 110S on a side away from the driving substrate 100. The light-emitting element 110 may be a red light-emitting diode, a green light-emitting diode, or a blue light-emitting diode, and is configured as a pixel of the display device 10 to provide display light to form a display image or as a characteristic light source for biometric identification. The light-emitting element 110 is, for example, a micro light-emitting diode (micro LED), a mini light-emitting diode (mini LED), or a light-emitting diode of other sizes, and the disclosure is not limited thereto. On the other hand, the light-emitting element 110 may be a vertical light-emitting diode or a flip-chip type light-emitting diode. For example, the electrode 111 located on the same side of the epitaxial structure of these light-emitting elements 110 may be aligned with the corresponding pads 101 on the driving substrate 100, and surface-mount technology (SMT) or mass transfer technology are used to establish a bond, so that the light-emitting element 110 and the driving substrate 100 are electrically connected. However, the disclosure is not limited thereto.

The light-shielding layer 120 is disposed between the light-emitting elements 110 to absorb the lateral light emission of the light-emitting elements 110 (e.g., light emitted towards direction X and direction Y, that is, the plane direction of the display device 10) and reduce optical cross talk between the light-emitting elements 110, thereby improving the contrast and resolution of the display device 10. The light-shielding layer 120 may be a black matrix (BM). The material of the light-shielding layer 120 includes a photoresist, and its optical density may be greater than 1. Of course, the disclosure is not limited thereto. The light-shielding layer 120 may have high absorption rate for the visible light band (e.g., 400 nm to 700 nm).

On the other hand, the light-shielding layer 120 may also be configured as an encapsulation layer. For example, the light-shielding layer 120 may cover and contact the upper surface 100S of the driving substrate 100 to protect the data lines or the scan lines of the driving substrate 100. The light-shielding layer 120 may also cover the pads 101 and electrodes 111 to isolate them from water vapor or oxygen intrusion. In addition, the light-shielding layer 120 may also directly contact and surround the sidewalls of the light-emitting element 110 to achieve the purpose of encapsulating, fixing and protecting the light-emitting element 110, thereby reducing the risk of the light-emitting element 110 peeling off or breaking when the display device 10 is impacted by an external force. The disclosure is not limited thereto.

On the other hand, the sensor 130 may have an upper surface 130S facing away from the driving substrate 100 for acquiring the information light EB from external sources. The information light EB may be an environmental light beam or a biometric light beam (e.g., a fingerprint image), etc., so that the display device 10 may acquire external information for response. For example, the display device 10 may include a solid-state processor or a control circuit (not shown) for adjusting the brightness of light emitted from the light-emitting element 110 in response to the intensity of the ambient light beam, thereby facilitating user viewing in low-light conditions. Alternatively, the display device 10 may be controlled in response to the biometric light beam to protect user privacy. The disclosure is not limited thereto. The sensor 130 may be a complementary metal-oxide semiconductor (CMOS), a charge coupled device (CCD), a photodiode, or other optical sensor, an infrared sensor, or other types of signal sensors, but the disclosure is not limited thereto.

It is worth mentioning that, based on the inconsistent sizes of different types of elements, the light-shielding layer 120 may have different heights or thicknesses corresponding to the positions of different elements. For example, the display device 10 may satisfy the following conditional expression: H1>H2>H3. H1 is the height from the light-emitting surface 110S to the upper surface 100S of the driving substrate 100, and may also represent the height of the light-emitting element 110 on the driving substrate 100. H2 is the height from the surface 120S of the light-shielding layer 120 to the upper surface 100S of the driving substrate 100, and may also represent the height of the light-shielding layer 120 on the driving substrate 100. H3 is the height from the upper surface 130S of the sensor 130 to the upper surface 100S of the driving substrate 100, and may also represent the height of the sensor 130 on the driving substrate 100.

Based on the above, since the height H1 is greater than the height H2, and the light-shielding layer 120 above the light-emitting surface 110S is removed during the manufacturing process of the display device 10 (described below) to expose the light-emitting surface 110S of the light-emitting element 110, the light-shielding layer 120 may not affect the forward light emission of the light-emitting element 110. On the other hand, since H2>H3, the light-shielding layer 120 may maintain a sufficient film thickness to fulfill its light-shielding capability. For example, when the height H2 of the light-shielding layer 120 is less than 3 microns, the transmittance in the visible light band or infrared light band significantly increases, resulting in a decrease in the light-shielding capability. On the other hand, a sufficiently large height H2 may further protect and stabilize the light-emitting element 110 and the sensor 130. In some embodiments, the light-shielding layer 120 may directly contact and surround the side wall 130W of the sensor 130. For related functions, reference may be made to the relevant paragraphs about the light-shielding layer 120 encapsulating the light-emitting element 110, and are not repeated herein.

It is worth mentioning that during the manufacturing process, part of the light-shielding layer 120 adheres to the sensing surface (e.g., the upper surface 130S) of the sensor 130. For example, the part 120P of the light-shielding layer 120 may cover the second portion 130S2 of the upper surface 130S, while exposing the first portion 130S1. However, the thickness D1 of the part 120P of the light-shielding layer 120 may be extremely low. In some embodiments, the thickness D2 of the light-shielding layer 120 contacting the sensor 130 may be greater than the thickness D1 of the light-shielding layer 120 above the upper surface 130S. In some embodiments, the thickness D1 may be less than 1 micron. Accordingly, the sensing function of the sensor 130 may be minimally affected, thus maintaining good sensing sensitivity.

In some embodiments, the display device 10 may further include an optical layer 140, and the optical layer 140 is used to contact the light-emitting elements 110 and the sensor 130. For example, the optical layer 140 may be disposed in the gaps between the light-emitting elements 110, contacting the light-emitting surface 110S and side surfaces of the light-emitting elements 110, or contacting the first portion 130S1 of the upper surface 130S of the sensor 130, to achieve the purpose of encapsulating and protecting the light-emitting element 110 and the sensor 130. The optical layer 140 includes, for example, optical clear adhesive (OCA), pressure sensitive adhesive (PSA), silicone adhesive, polyurethane reactive (PUR) adhesive, polyurethane adhesive, or other suitable optical grade adhesive. Preferably, the optical layer 140 selectively be an optical adhesive material with a high transmittance, for example, the transmittance of the visible light band or the infrared light band may be greater than 90%, but not limited thereto.

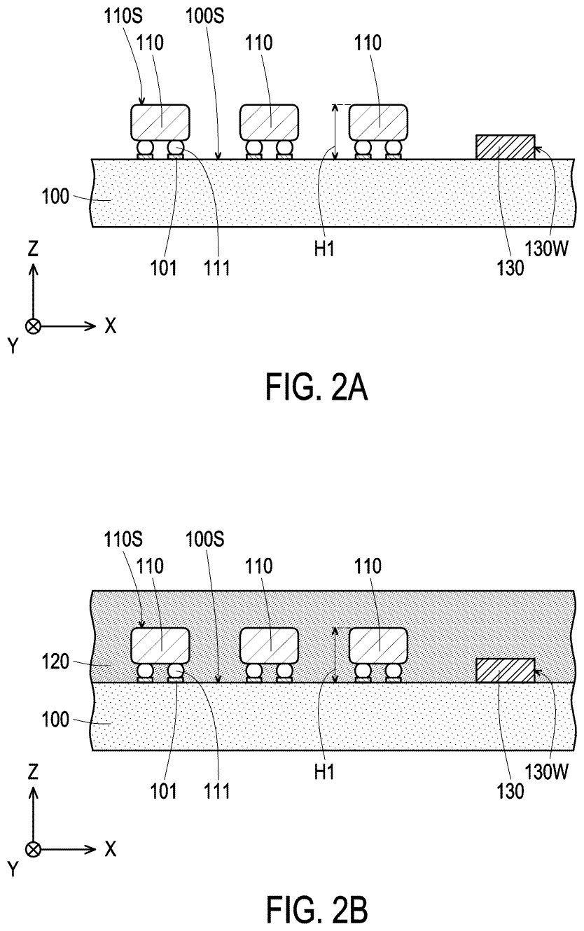

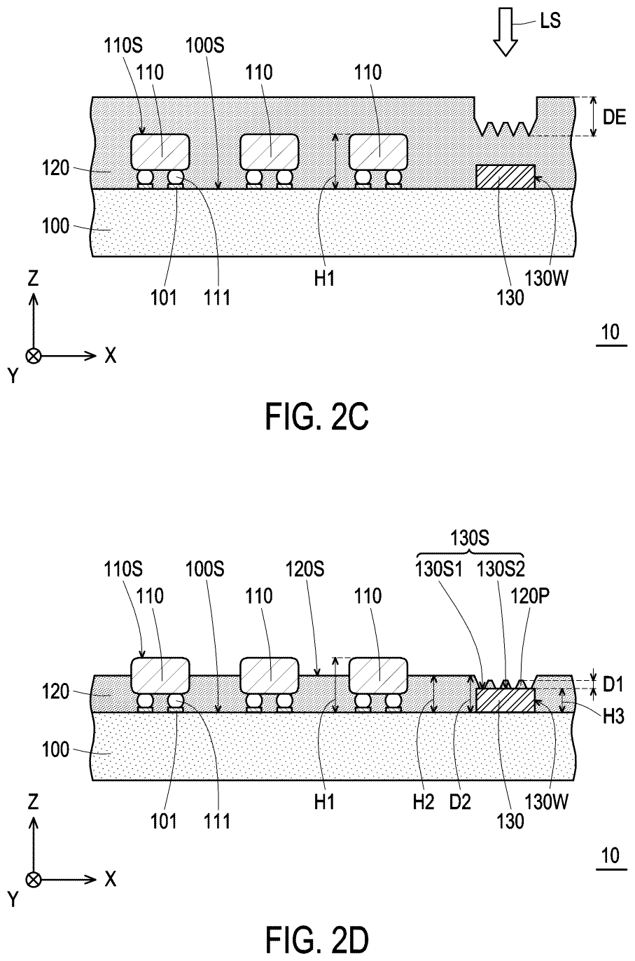

FIG. 2A to FIG. 2D are schematic diagrams of the manufacturing process of the display device of an embodiment of the disclosure. Referring to FIG. 2A, the driving substrate 100 is first disposed, and multiple light-emitting elements 110 and the sensor 130 are disposed on the driving substrate 100 by using mass transfer technology or surface-mount technology and are electrically connected to the driving substrate 100.

Next, referring to FIG. 2B, the material of the light-shielding layer 120 is coated on the driving substrate 100, and the light-shielding layer 120 may further cover the upper surface 100S of the driving substrate 100 and be disposed in the gap of each light-emitting element 110. The light-shielding layer 120 covers the light-emitting surface 110S of the light-emitting element 110. The light-shielding layer 120 covers the sensor 130 and the sidewall 130W of the sensor 130. The coating method of the light-shielding layer 120 may be, for example, spin coating or roller coating, but the disclosure is not limited thereto.

Next, referring to FIG. 2C, a portion of the light-shielding layer 120 is first removed using a laser LS process. For example, laser micro-etching equipment may be used to etch the light-shielding layer 120 overlapping the sensor 130 so that the light-shielding layer 120 has an etching depth DE. The wavelength band of the laser LS may be, for example, the ultraviolet light band, and the wavelength may be selected as, for example, 355 nanometer ultraviolet laser, but the disclosure is not limited thereto. The pulse width of the laser LS (i.e., the duration of each laser irradiation) may be about a picosecond (10-12 second), and the disclosure is not limited thereto. In some embodiments, the power of the laser LS may be less than 1 watt, the number of scans of the laser LS on the light-shielding layer 120 may be greater than ten times, and the spot diameter formed by the laser LS on the light-shielding layer 120 may be substantially 10 microns, but the disclosure is not limited thereto. The laser etching process with a number of scans that is low power and high frequency facilitates in controlling the uniformity of the etching depth DE, and may also ensure that the light-shielding layer 120 is not burned (e.g., if the power of the laser LS is greater than 1 watt, there is a risk of the light-shielding layer 120 being burned). Preferably, the power of the laser LS power may be 0.2 watts; the number of scans may be more than 16 times. On the other hand, the aforementioned arrangement may prevent the etching depth DE from becoming too deep, thereby averting damage from the laser LS to the sensor 130, and the use of laser LS process may also ensure the precision of the scanning area.

Next, referring to FIG. 2D, another portion of the light-shielding layer 120 is removed. For example, a microwave plasma etching or wet etching process may be used for a large-area removal of the light-shielding layer 120 on the light-emitting surface 110S and the light-shielding layer 120 on the upper surface 130S, to expose part of the surface of the light-emitting surface 110S and the upper surface 130S (e.g., the first portion 130S1 may not have the light-shielding layer 120). Since there is an etching depth DE above the sensor 130 in the process of FIG. 2C, during the process of uniformly etching the entire light-shielding layer 120 in FIG. 2D, it may be ensured that when the upper surface 130S is exposed, the light-shielding layer 120 still has sufficient thickness in the remaining positions (i.e., the height H2 is large enough). While ensuring that the sensor 130 is not affected by the light-shielding layer 120, the light-shielding capability of the light-shielding layer 120 may also be maintained, so that the display device 10 has good contrast, may exhibit the characteristics of an integrated black panel, and has good sensing capabilities.

On the contrary, if the laser etching process of FIG. 2C is not performed, since the height H3 of the sensor 130 is generally less than the height H1 of the light-emitting element 110, if only the light emission of the light-emitting element 110 is considered and only the light-shielding layer 120 is only etched to the height H1 in the etching process of FIG. 2D, the light-shielding layer 120 on the upper surface 130S of the sensor 130 will still have a sufficient thickness D1, which greatly affects the light sensing capability of the sensor 130. For another example, if only the sensing capability of the sensor 130 is considered, and the light-shielding layer 120 is etched to height H3 in the etching process of FIG. 2D, the light-shielding capability of the light-shielding layer 120 will be insufficient, affecting the contrast of the display device 10. In other words, through the above process of the embodiment of the disclosure, the above problems may be solved at the same time to ensure the sensing function and display quality of the display device 10.

After the above-mentioned process steps of FIG. 2D, the aforementioned optical layer 140 may be further disposed to contact the light-emitting elements 110 and the sensor 130 to achieve the purpose of encapsulating each electrical element. The disposition method of the optical layer 140 may be, for example, spin coating or roller coating, but the disclosure is not limited thereto. Accordingly, the display device 10 of FIG. 1 may be initially completed.

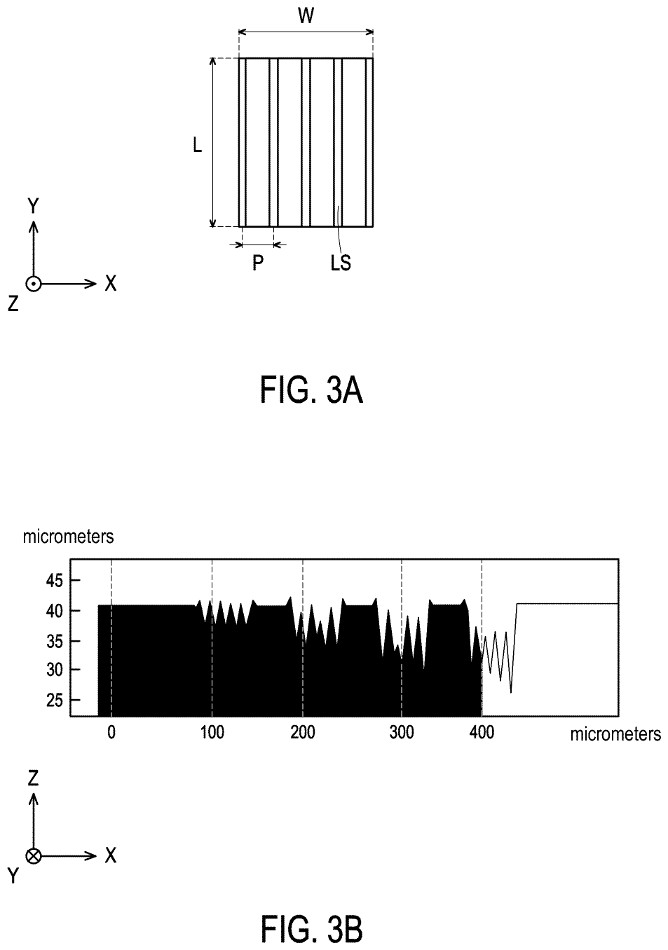

FIG. 3A to FIG. 3B are respectively a top view schematic diagram and a cross-sectional schematic diagram of a laser process. FIG. 3A schematically shows the relationship between the scanning path of the laser LS on the sensor 130. For example, on an area with a width W of about 40 microns and a length L of about 70 microns, the pitch P of the laser LS may be about 10 microns. In some embodiments, the pitch P may be less than 10 microns. On the other hand, FIG. 3B shows the relationship between the thickness of the light-shielding layer 120 and the number scans of the laser LS. Specifically, the horizontal axis parameter 0 to 100 microns is the depth formed by scanning the light-shielding layer 120 the laser LS once (e.g., using a picosecond laser, in which the wavelength of 355 nm, and the spot diameter of the laser LS is about 10 microns). From 100 to 200 microns is the depth formed by scanning the light-shielding layer 120 with the laser LS twice. From 200 to 300 microns is the depth formed by scanning the light-shielding layer 120 with the laser LS three times. From 300 to 400 microns is the depth formed by scanning the light-shielding layer 120 with the laser LS four times. It may be observed that as the number of scans increases and the pitch P decreases, the jagged traces on the etched surface of the light-shielding layer 120 becomes smaller, which is more beneficial to the surface flatness of the etched surface.

To sum up, for the display device, a portion of the light-shielding layer above the sensor may first be removed through a laser process, and then other processes (e.g., an etching process) may be used for a large-area removal of the rest of the light-shielding layer to avoid affecting the light output of the display beam. The laser process may accurately control the depth of the light-shielding layer, so even if the height of the sensor is less than the height of the light-emitting element, the display device and the manufacturing method thereof of the disclosure may still ensure that the thickness of the light-shielding layer on the sensor is low enough so as not to affect the ability of the sensor to receive external information while taking into account the light-shielding capability of the light-shielding layer at other locations, so that the sensor has good sensitivity. Therefore, the sensing capability of the display device is improved and high contrast is maintained.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A display device, comprising:
a driving substrate;
a plurality of light-emitting elements, disposed on the driving substrate, each of the light-emitting elements comprises a light-emitting surface;
a light-shielding layer, disposed between the light-emitting elements; and
a sensor, disposed on the driving substrate and having an upper surface facing away from the driving substrate,
wherein following conditional expression is further satisfied: H1>H2>H3, H1 is a height from the light-emitting surface to the driving substrate, H2 is a height of the light-shielding layer on the driving substrate, H3 is a height from the upper surface to the driving substrate,
wherein the light-shielding layer further covers part of the upper surface.

2. The display device according to claim 1, wherein the light-emitting elements are micro light-emitting diodes.

3. The display device according to claim 1, further comprising an optical layer, contacting the light-emitting elements and the sensor.

4. The display device according to claim 1, wherein the light-shielding layer surrounds each of the light-emitting elements and contacts the light-emitting elements and the sensor, wherein H2>3 microns.

5. The display device according to claim 1, wherein the sensor is an infrared sensor or an ambient light sensor.

6. The display device according to claim 1, wherein part of the upper surface is not covered by the light-shielding layer.

7. The display device according to claim 1, wherein the light-shielding layer contacts and surrounds a sidewall of the sensor, wherein a thickness of the light-shielding layer contacting the sensor is greater than a thickness of the light-shielding layer above the upper surface.

8. The display device according to claim 7, wherein the thickness of the light-shielding layer above the upper surface is less than 1 micron.

9. A manufacturing method of a display device, comprising:
disposing a driving substrate;
disposing a plurality of light-emitting elements on the driving substrate;
disposing a sensor on the driving substrate;
disposing a light-shielding layer on the light-emitting elements, on the sensor, and between the light-emitting elements; and
first removing part of the light-shielding layer on the sensor through a laser, and then removing another part of the light-shielding layer on the light-emitting elements and the sensor.

10. The manufacturing method of the display device according to claim 9, wherein after removing the another part of the light-shielding layer, an optical layer is disposed to contact the light-emitting elements and the sensor.

11. The manufacturing method of the display device according to claim 9, wherein a thickness of the light-shielding layer on the sensor is less than 1 micron.

12. The manufacturing method of the display device according to claim 9, wherein power of the laser is less than 1 watt, a number of scans of the laser is greater than ten times, and a spot diameter of the laser is substantially 10 microns.

13. The manufacturing method of the display device according to claim 9, wherein during a process of removing the part of the light-shielding layer on the sensor through the laser, the light-shielding layer exposes part of a surface of the sensor.

14. The manufacturing method of the display device according to claim 12, wherein a pitch of a scan track of the laser is less than or equal to 10 microns.
